(19) United States
(12) Patent Application Publication
(10) Pub. No.: US 2003/0056366 A1
(43) Pub. Date: Mar. 27, 2003

(54) Printed circuit board and method for manufacturing the same

(76) Inventor: Peng-Jui Peng, Taoyuan City (TW)

Correspondence Address: BIRCH STEWART KOLASCH & BIRCH, PO BOX 747, FALLS CHURCH, VA, 22040-0747, US

(21) Appl. No.: 10/133,311

(22) Filed: Apr. 29, 2002

(30) Foreign Application Priority Data
Sep. 26, 2001 (TW) 90123687

(51) Int. Cl. H01K 3/10; H05K 3/02

(52) U.S. Cl. 29/852; 29/847

(57) ABSTRACT

A printed circuit board and a method for manufacturing the same has a layer of metal-contained protective lacquer coating on the outmost surfaces of the printed circuit board. The metal content of the protective lacquer gives the printed circuit board improved heat radiation effects, increases PCB performance and stability, and slows aging.

### FIELD OF THE INVENTION

The invention relates to a printed circuit board and a method for manufacturing the same, and particularly to a printed circuit board with a surface coating of metal-contained protective lacquer and a method for manufacturing the same.

### BACKGROUND OF THE INVENTION

A Printed Circuit Board (PCB) is a board made from non-conductive materials such as plastics with electric circuits formed thereon by employing printing techniques. Electronic elements such as integrated circuits and resistors are mounted thereon. The PCBs thus made have been widely used for computer main boards and interface cards. Conventional methods for manufacturing PCBs include: first, providing a substrate; then bonding one or both surfaces of the substrate with copper cladding to form a copper-clad substrate; forming through holes on both sides of the copper-clad substrate; plating a cover layer on the side wall of the through holes; forming electric circuits on the copper-clad substrate by etching, coating a photoresist agent and exposing processes; processing follow-on fabrication operations; and finally forming a solder mask through Hot Air Solder Leveling (HASL) to complete the manufacturing of a single layer PCB. Another approach includes a bonding process after the electric circuits are formed on the copper-clad substrate to bond a plurality of copper-clad substrates to become a laminate; then fabrication operations are done to complete the manufacturing of a multi-layer PCB.

Taking interface cards of computer systems as an example, they are coupled with main boards, central processing units (CPUs), and memory devices to operate for a long period of time. Their surfaces are coated with turpentine-contained material (also a solder mask) and do not have desirable heat radiation effects. As a result, operation performance of the interface cards suffers. Moreover, the interface cards are constantly subject to radiation and high temperature baking of various products, so the PCBs with turpentine-contained material tend to age gradually and insulation materials tend to become conductive. Such phenomena create serious problems. Once the PCBs are aged, they become brittle and have great potential risks.

### SUMMARY OF THE INVENTION

The object of the invention is to resolve the aforesaid problems by providing a printed circuit board (PCB) and a method for manufacturing the same, to improve heat radiation effects of the PCB and enhance PCB performance, stability and durability.

The method for manufacturing the PCB according to the invention includes: first, providing a substrate; coating a copper cladding on the surface of two opposite sides of the substrate; forming through holes on the substrate and the copper claddings on two sides at selected locations; plating a layer of chemical copper to cover the substrate and inner side walls of the through holes; employing image transfer and etching techniques, including pattern, plating copper, soldering and etching to form circuits on the substrate; coating a solder mask on the surfaces of the substrate, and leveling solder on the periphery of the through holes to increase electric conductivity; finally coating a layer of metal-contained protective lacquer on the solder mask to form the PCB for making desired circuit board products.

The PCB disclosed in the invention has a layer of protective lacquer to cover the solder mask. The protective lacquer contains metal such as metal powder. The PCB thus made has improved heat radiation effects and can enhance PCB performance, stability and durability.

The foregoing, as well as additional objects, features and advantages of the invention will be more readily apparent from the following detailed description, which proceeds with reference to the accompanying drawings.

### BRIEF DESCRIPTION OF THE DRAWINGS

FIGS. 1A through 1K are schematic views of manufacturing processes according to the invention.

### DESCRIPTION OF THE PREFERRED EMBODIMENT

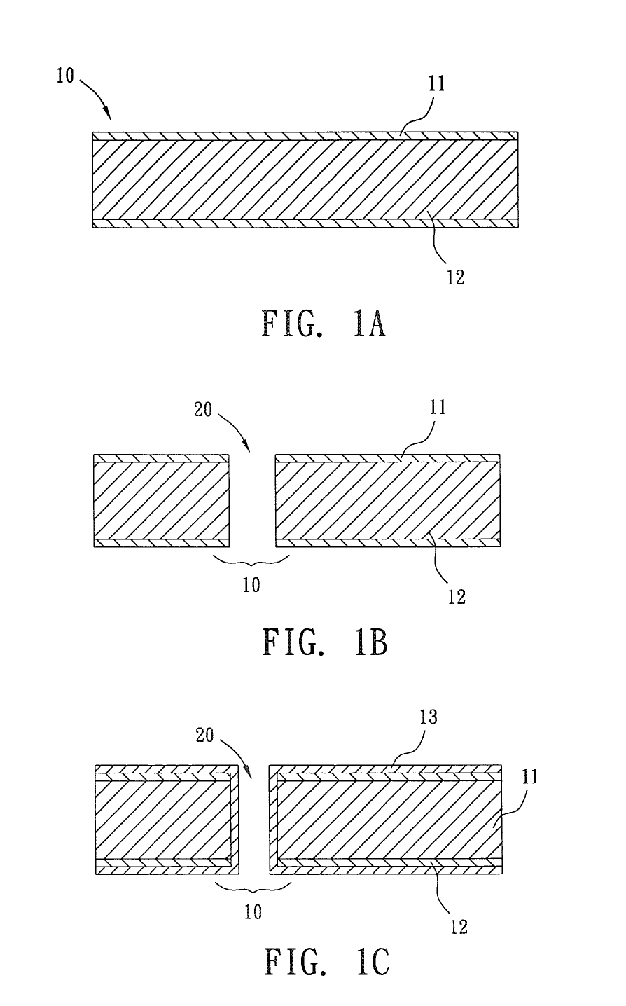

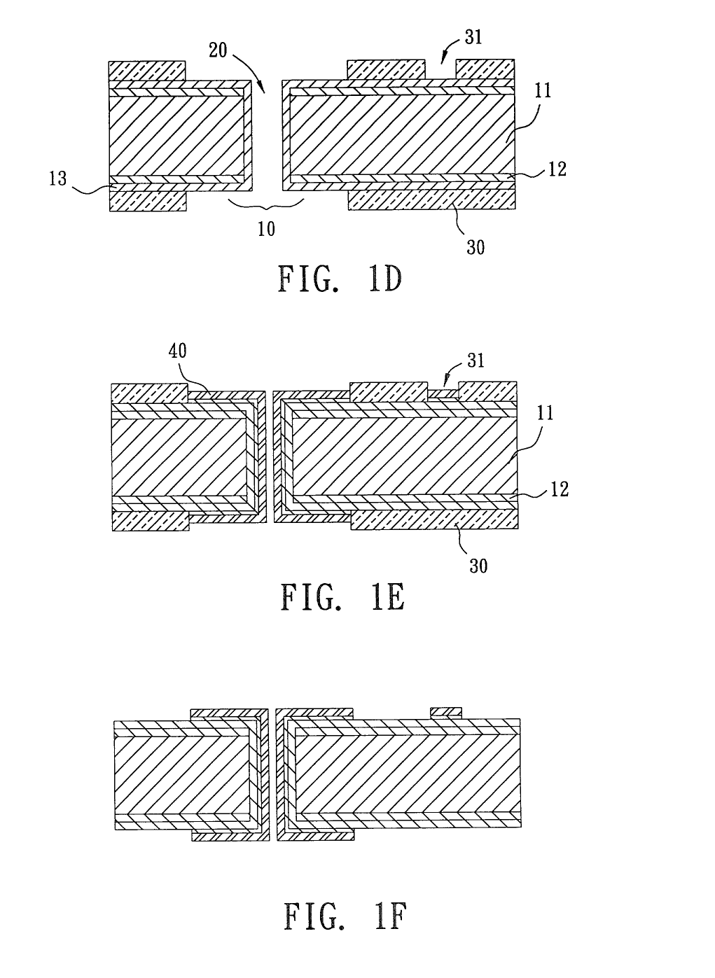

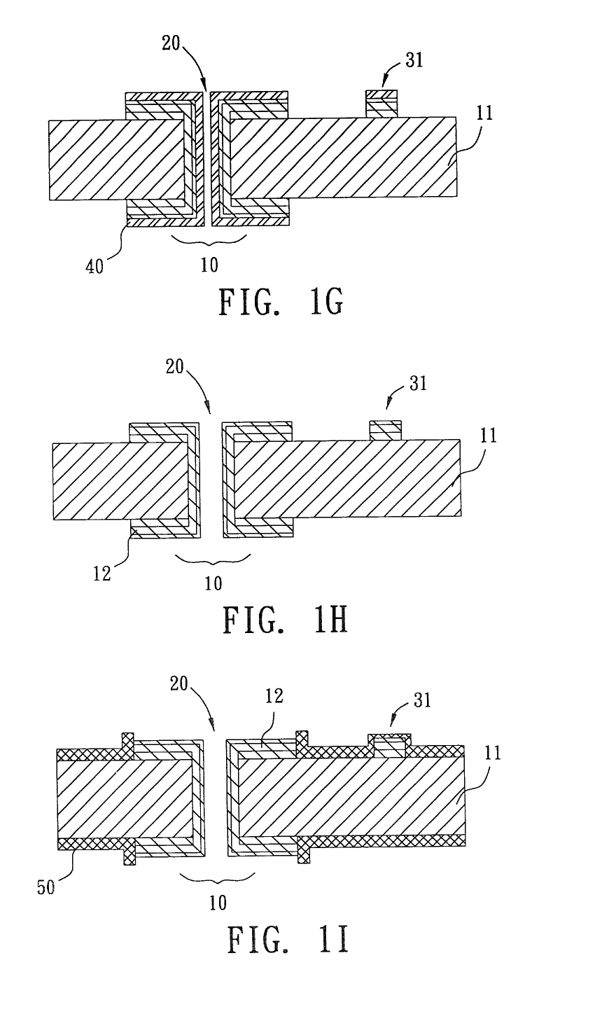

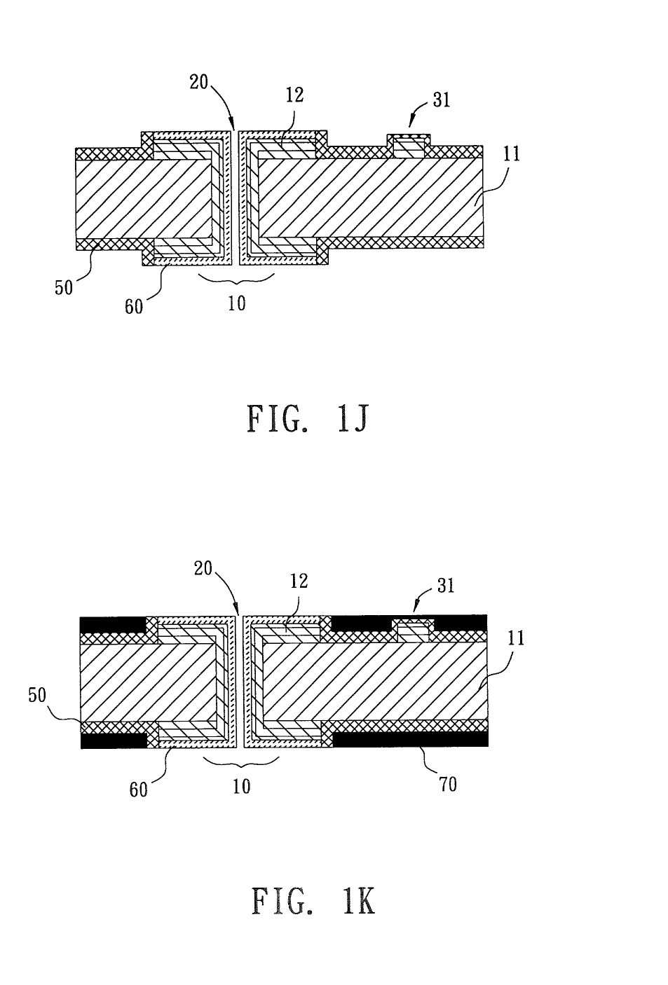

The invention aims at providing a printed circuit board (PCB) and a method for manufacturing the same. Referring to FIG. 1A, first, a substrate 10 is provided. The substrate 10 is made from glass fibers 12 (such as fireproof material FR4 or the like). The surfaces of two opposite sides of the substrate are covered by copper claddings 11. At selected locations, through holes 20 are directly drilled and formed to run through the substrate 10 and the copper claddings 11 on two sides in a hole or through hole fashion (the multi-layer substrate is drilled after lamination is finished; the drawings and discussion focus on a single layer substrate) (referring to FIG. 1B).

The through holes 20 are then plated with a layer of chemical copper 13 to form Plated Through Holes (PTHs). Because it is not practical to plate only the through holes, the entire substrate 10 is plated (as shown in FIG. 1C). Then techniques of image transfer and etching are employed to form the required circuits on the substrate 10.

It is employing a pattern and exposing and image developing operations to transfer desired images on the substrate 10 (as shown in FIG. 1D, the required circuit 31 is on the right side; the pattern 30 is plate-resistant, hence there is no plating on the location where the pattern 30 is formed). Process pattern plating by plating copper on the circuits 31, as shown in FIG. 1E. Then plate tin lead 40 to serve as an etching resistant agent to protect the covered copper conductors from eroding by alkalis.

Then the plate-resistant pattern 30 is peeled and removed by means of a selected chemical agent, as shown in FIG. 1F. An erosive agent is used to dissolve the copper in the nonconductive portion. The process set forth above is etching and is applied on the portion without the protection of the tin lead 40 (i.e. the nonconductive portion other than the circuits 31 or through holes 20) (referring to FIG. 1G). Finally, the etching-resistant layer of the plated tin lead 40 is removed (whether it is a pure tin layer or a tin-lead alloy). The tin-lead layer serves the purpose of resisting etching, so once the etching process is completed, it should be removed (shown in FIG. 1H).

Referring to FIG. 1I, the surfaces of the substrate 10 are coated with a solder mask or solder resist 50 to cover the entire circuits 31 and copper surfaces except the through holes 20 and other solder pads (not shown in the drawings). This process is to prevent short circuits during soldering operations, save solder materials, and to prevent moisture and other electrolytic materials from contaminating or oxidizing the circuits and resulting in a downgrade of electrical properties. The solder mask can also prevent damage to the surfaces of the substrate resulting from external mechanical impact, and maintain desired insulation.

Then a Hot Air Solder Leveling (HASL) process is performed to form a solder layer 60 to protect the copper surface and provide a desired soldering base for the following processes (referring to FIG. 1J). Coat a layer of protective lacquer 70 on the solder mask 50. The protective lacquer 70 contains metal to increase heat radiation effects (as shown in FIG. 1K). Then manufacturing processes of the PCB are completed. The PCB thus made may be used in the following processes such as forming, testing, finishing, and assembling.

As previously discussed, the protective lacquer 70 contains metal which may be silver powder, aluminum powder, gold powder, copper powder or the like—materials which have excellent heat conductivity. The main content is resin or modified polysterresin or the like. As metal has good heat conductivity, the PCB also has more desirable heat radiation properties. In addition, mica powder or the like may be included to add gloss and a metallic sheen to the protective lacquer 70, and to give the PCB an attractive appearance. The following experiment of the protective lacquer 70 is mainly based on resin or modified polysterresin, the metal powder is aluminum powder, and selected ketone and ester has been included. It clearly indicates that heat radiation effects are improved significantly. Because of improved heat radiation properties, the PCBs thus made can be adapted for use in other products such as display cards and other types of interface cards. In addition, to provide higher stability and greater performance, aging of the solder mask can be prevented. Thus aging speed of PCBs may also be reduced and the time-span of the product's usefulness can be increased. As a result, potential risks can be eliminated. Moreover, the problem of electro magnetic interference (EMI) that has become a great concern in recent years can also be overcome by means of the invention. Test results of the invention all meet required standards.

The manufacturing processes set forth above focus on single layer PCBs. They can also be adopted equally well for multi-layer PCBs. Details are omitted herein.

In summary, the invention can achieve the following effects:

The invention provides a printed circuit board (PCB) and a method for manufacturing the same. It involves coating a layer of protective lacquer on the exterior of the solder mask of the PCB. The protective lacquer contains metal such as silver powder, aluminum powder and the like. As a result, heat radiation effects of the PCB are improved, performance and stability of the PCB are enhanced, and aging of the PCB can also be slowed.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A method for manufacturing printed circuit boards, comprising the steps of:
providing a substrate having two side surfaces covered respectively by a copper cladding;
forming at least one through hole running through the substrate and the copper claddings at selected locations;
plating chemical copper on the surfaces of the substrate and side walls of the through hole;
employing image transfer and etching techniques to form circuits on the surfaces of the substrate;
coating a solder mask on the surfaces of the substrate;
performing hot air solder leveling in the through hole and on locations reserved for solder pads; and
coating metal-contained protective lacquer on the solder mask.

2. The method of claim 1, wherein the protective lacquer includes metal powder.

3. The method of claim 2, wherein the metal powder is aluminum powder.

4. The method of claim 2, wherein the metal powder is silver powder.

5. A printed circuit board comprising a layer of metal-contained protective lacquer coating on surfaces thereof.

6. The printed circuit board of claim 5, wherein the protective lacquer includes metal powder.

7. The printed circuit board of claim 6, wherein the metal powder is aluminum powder.

8. The printed circuit board of claim 6, wherein the metal powder is silver powder.
